(19) United States
(12) Patent Application Publication
(10) Pub. No.: US 2021/0389112 A1
(43) Pub. Date: Dec. 16, 2021

(54) DETECTION DEVICES

(71) Applicant: Hewlett-Packard Development Company, L.P., Spring, TX (US)

(72) Inventors: Hai-Lung Hung, Taipei City (TW); Cheng-Yi Yang, Taipei City (TW); Szu Tao Tong, Taipei City (TW)

(73) Assignee: Hewlett-Packard Development Company, L.P., Spring, TX (US)

(21) Appl. No.: 17/288,935

(22) PCT Filed: Dec. 11, 2018
(86) PCT No.: PCT/US2018/064880

§ 371 Date: Apr. 27, 2021

(51) Int. Cl. G01B 5/25; H05K 7/20

(52) U.S. Cl. CPC G01B 5/25; H05K 7/2039

(57) ABSTRACT

A detection device includes: a body; a first set of at least three contact areas on the body to contact a corresponding set of at least three contact areas of a central processing unit (CPU) cover; and a second set of at least three contact areas on the body to contact a set of at least three contact areas on heatsink componentry. An incorrect assembly position of a heatsink is indicated when one or more points of contact with the heatsink componentry and the CPU cover is incorrect.

### BACKGROUND

A heatsink dissipates heat away from a central processing unit (CPU) to thereby maintain a computer at optimal running temperatures. Proper assembly of a heatsink allows the heatsink to function properly and avoid the CPU from running at higher than normal temperatures.

### BRIEF DESCRIPTION OF THE DRAWINGS

The accompanying drawings illustrate various implementations of the principles described herein and are a part of the specification. The illustrated implementations are merely examples and do not limit the scope of the claims.

FIG. 1 illustrates a perspective view of a detection device according to an example of principles described herein.

FIG. 2 illustrates a perspective view of a heatsink according to an example of principles described herein.

FIG. 3 illustrates a perspective view of a heatsink assembly according to an example of principles described herein.

FIG. 4 illustrates a perspective view of a cover according to an example of principles described herein.

FIG. 5 illustrates a perspective view of a cover according to an example of principles described herein.

FIG. 6 illustrates an exploded view of a heatsink assembly according to an example of principles described herein.

FIG. 7 illustrates a front view of a heatsink assembly according to an example of principles described herein.

FIG. 8 illustrates a perspective view of a heatsink assembly according to an example of principles described herein.

FIG. 9 illustrates a perspective view of a heatsink assembly according to an example of principles described herein.

FIG. 10 illustrates a flowchart of a method for using a detection device according to an example of principles described herein.

Throughout the drawings, identical reference numbers designate similar, but not necessarily identical, elements.

### DETAILED DESCRIPTION

The following relates to a detection device that is used to detect proper installation of a heatsink assembly on a circuit board. Current assembly technology lacks any kind of heatsink detection without an assembly operator powering the CPU and hearing a feedback alert warning if there is a problem detected.

Specifically, the detection device includes a body that is installed between a heatsink and a CPU cover. If the heatsink screws are not assembled correctly, then the CPU cover will not be able to be installed properly due to the detection device interference with the heatsink and the CPU cover.

An example detection device is described with a body having a first set of contacts that contact a corresponding set of contacts of a CPU cover. The body has a second set of contacts that contact a set of contacts on heatsink componentry. At least three contact areas are used in each set to provide alignment and balance of the cover with the body and heatsink when the heatsink is assembled correctly. An imbalance of the cover occurs when the heatsink is assembled incorrectly.

Another example detection device is described with a body having a plurality of contact areas located on a top surface or aspect of the body. The body further includes a plurality of bottom contact areas located on a bottom surface or aspect of the body. The plurality of top contact areas is positioned to align with and contact corresponding contacts on a cover and the plurality of bottom contact areas are positioned to align with and contact corresponding contacts on heatsink componentry when the heatsink is assembled correctly. Furthermore, a planar surface on the body lays parallel to a planar surface of a heatsink in the correct assembly. An imbalance of the cover occurs when the heatsink is assembled incorrectly.

A method for physically detecting a correct assembly position of a heatsink is accomplished by placing a detection device on at least three contact areas of heatsink componentry. The cover is placed over the detection device. If the cover is not properly aligned or balanced relative to the heatsink componentry, this indicates that the heatsink is assembled incorrectly and the cover may be removed and the heatsink reinstalled.

In the following description, for purposes of explanation, specific details are set forth in order to provide a thorough understanding of the disclosure. It will be apparent, however, to one skilled in the art that examples consistent with the present disclosure may be practiced without these specific details. Reference in the specification to “an implementation,” “an example” or similar language means that a particular feature, structure, or characteristic described in connection with the implementation or example is included in at least that one implementation, but not necessarily in other implementations. The various instances of the phrase “in one implementation” or similar phrases in various places in the specification are not necessarily all referring to the same implementation.

In an example, a detection device includes: a body; a first set of at least three contact areas on the body to contact a corresponding set of at least three contact areas of a CPU cover; and a second set of at least three contact areas on the body to contact a set of at least three contact areas on heatsink componentry. An incorrect assembly position of a heatsink is indicated when points of contact with the heatsink componentry and the CPU cover is incorrect.

In another example, a method for physically detecting a correct assembly position of a heatsink includes: placing a detection device on at least three contact areas of heatsink componentry; placing a cover over the detection device; and removing the cover and the detection device if the cover is not properly aligned or balanced relative to the heatsink componentry that is mounted on the heatsink.

In another example, a detection device includes: a body; a plurality of top contact areas on a top surface of the body; and a plurality of bottom contact areas on a bottom surface of the body, the plurality of top contact areas positioned to align with and contact corresponding contacts on a cover and the plurality of bottom contact areas positioned to align with and contact corresponding contacts on heatsink componentry when the heatsink is assembled correctly.

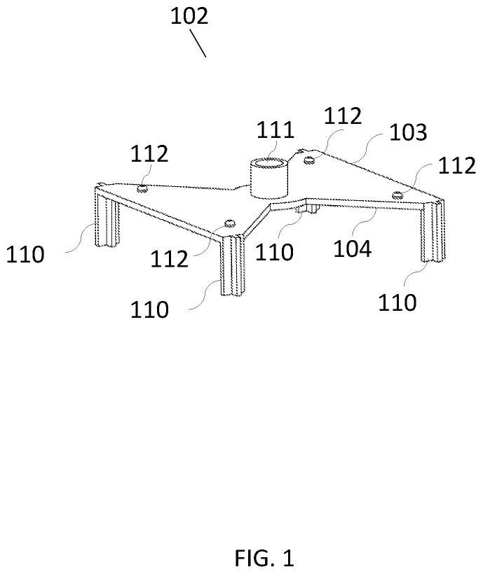

Turning to FIG. 1, a detection device 102 is shown according to an example of principles described herein. The body 103 includes a flat planar surface 104 of generally uniform thickness. The planar surface 104 includes a narrow midsection and two angled or fan shaped extensions, resembling a flattened bowtie. Opposing outer edges of the fan shaped extensions are straight and parallel relative to each other. The narrow midsection has slightly curved outer edges so as to follow curves of a central opening discussed below. Variations of the narrow midsection may include straight outer edges.

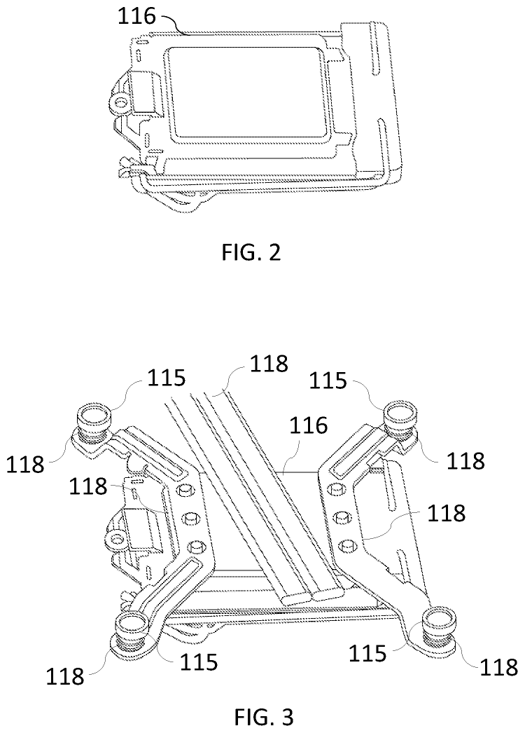

The length and width of the planar surface 104 are dimensioned to span the length and width of a heat sink, which is generally rectangular in shape (see FIG. 2). The area not covered due to the narrow midsection and angled or fan shaped extensions allows space for air to circulate and thereby heighten the efficiency of a nearby fan and heatsink. The planar surface may further include perforations in furtherance of promoting air circulation.

Instead of the planar surface 104 having fan shaped extensions, the planar surface may be another shape, such as rectangular or circular, or the planar surface may incorporate a square, rectangle, circle, oval, triangle, or other shape. The top and bottom surface of the body 103 may have variations like rounded surfaces or other curvature. The planar surface may include a flat upper surface that is parallel with a surface of a CPU cover when the heatsink and the body are in a correct assembly position. Alternatives include a flat lower surface that is parallel with the surface of a CPU cover. Either or both the upper and lower surface may be parallel with an upper or lower surface of the CPU cover during a correct assembly.

The body 103 further includes a first and second plurality of contact areas. The first plurality or set of at least three contact areas comprises extended members or protrusions from the body. The first set 112, as shown in FIG. 1, includes a plurality of raised bumps with rounded outer surfaces located on top of the planar surface 104 near or at corners of the planar extensions. The rounded outer surfaces may be in the form of half dome or half sphere like members. In other variations, the contact areas 112 may be flat or pointed, include extensions, recesses, or have other features.

The second set or plurality of contact areas includes a plurality of members that extend away from the body 103. As depicted in FIG. 1, the second set of at least three contact areas comprises elongated legs 110 that extend outward from the body. Four elongated legs 110 located at corners of the planar surface 104 extend perpendicularly away from the planar surface 104. Although four elongated legs 110 are shown, a plurality of members, such as three elongated legs or more than four elongated legs may be used.

The elongated legs 110 are straight members of equal length. The elongated legs extend outward from opposing corners of the body. Furthermore, the elongated legs extend outward from the body in a parallel manner. Also, the elongated legs extend in an opposite direction from the at least three contact areas in the first set.

As shown, the elongated legs 110 each have a cross section that forms a plus sign, or in other words, a cross section formed by a set of four walls that are perpendicular to each other so as to define a criss-cross shape. The elongated legs 110 originate at corners of the angled or fan shaped extensions. Corners of the angled fan shaped extensions, rather than ending in a sharp point formed by ordinary angular corners, include a wall of the perpendicular walls extending outwardly from the angled edges of the angled fan shaped extensions, the wall extending in parallel manner with the opposing outer edges of the angled fan shaped extensions. The other three walls of the perpendicular walls do not extend past opposing outer edges of the planar surface and edges of the two angled or fan shaped extensions.

The criss-cross shape or other shape of the elongated legs may be useful in providing added surface area for air flow and thus promote added heat dissipation.

Free ends of the elongated legs 110 are shaped to rest within recesses of the heatsink componentry, balance on top of the heatsink componentry, or otherwise be mounted on the heatsink componentry. To that end, the free ends may be flat, rounded, recessed, pointed, or have another shape that corresponds to surfaces of heatsink componentry.

Variations include that the elongated legs be angled so as to be slanted instead of perpendicular relative to the planar surface 104. The legs may further have a square, rectangle, circle, oval, or other cross-sectional shape. The walls that form a perpendicular cross section may, instead of being perpendicular, be angled with each other to form an angular cross section. Instead of perpendicular walls, the elongated legs may be formed by single walls with a square or rectangular cross section. The angle of the corner of the planar surface would change accordingly by having a pointed edge formed by a corner of the square or rectangular wall or other cross section shape.

Also included with the detection device 102 is an arm 111 that extends outwardly from the body to be slidably received through an opening of the CPU cover, the arm to align the body with the cover. The arm may have a diameter that allows for a friction fit within the opening of the cover. Alternatively, the diameter of the arm may have sufficient clearance such that there is very little or no contact with inner walls of the opening of the cover. A sufficient clearance is one that allows the arm enough space to move laterally and angularly within the opening of the cover and thus reposition the detection device relative to a heatsink and heatsink componentry.

The arm 11 extends outward perpendicularly from the body 103 in an opposite direction from the elongated legs 110. The arm 111 as shown is located at the central midsection of the planar surface 104 of the body 103. The arm 111 includes a cylindrical member with a hollow central opening therethrough. Alternatively, the cylindrical member may be solid or only partially hollowed.

The arm extends in parallel manner with the first set of contacts that include raised bumps, extended members, or protrusions. The arm has a greater length than the first set of contacts so that it can be inserted within an opening of the cover and reach to top edges that define the opening or extend past the top edges that define the opening. The arm may have a length that allows the arm to be manipulated by a tool. Also, the arm may have a length that may be manipulated by fingers of standard anatomical size conventions that are typical for manipulating tools and instruments related to CPUs.

The material of the body may include metal, plastic, glass, silicone, composites, etc. The first and second set of contact areas may be of the same material or different material as the planar surface. For example, the first set of contact areas may be made of silicone while the body and the second set of contact areas are made of metal. Silicone contact areas may provide for a friction fit with a corresponding recessed contact area of a cover.

The body may include properties that make it rigid or semi-rigid. Additionally, the body may be pliable such that it bends. For example, the body may include properties of being elastomeric such that the body can be stretched under stress but then return to its original unstretched state once the stress is removed.

The surface of the body may be smooth, rough, or have a mixture of smooth and rough areas as desired. For example, the top of the body may be rough to cause sliding friction between the cover and the body and thus reduce undesired movement between the cover and the body.

Turning to FIG. 2, an example heatsink 116 is shown. The heatsink 116 may include a plurality of fins or other elements that promote heat dissipation. The heatsink 116 may further comprise one or more fans that promote air flow over surface areas, including the fins and other areas of the heatsink 116. The heatsink 116 may have a somewhat flat shape that is square, rectangular, or another shape.

FIG. 3 shows heatsink componentry 118 that is used to secure the heatsink 116 to a board. In particular, the heatsink componentry 118 includes screws and fastening elements that are used to secure the heatsink 116 to a board with the heatsink 116 secured between the fasteners and a board. The heatsink componentry screws 118 include contact areas 115 that include flat surfaces, flat rims, and flat recesses.

Alternatively, contact areas may be located on the fastening elements that include generally flat, elongated bars or clips that run across portions of the heatsink. Elongated legs are positioned on the detection device to be aligned with the contact areas wherever they are located.

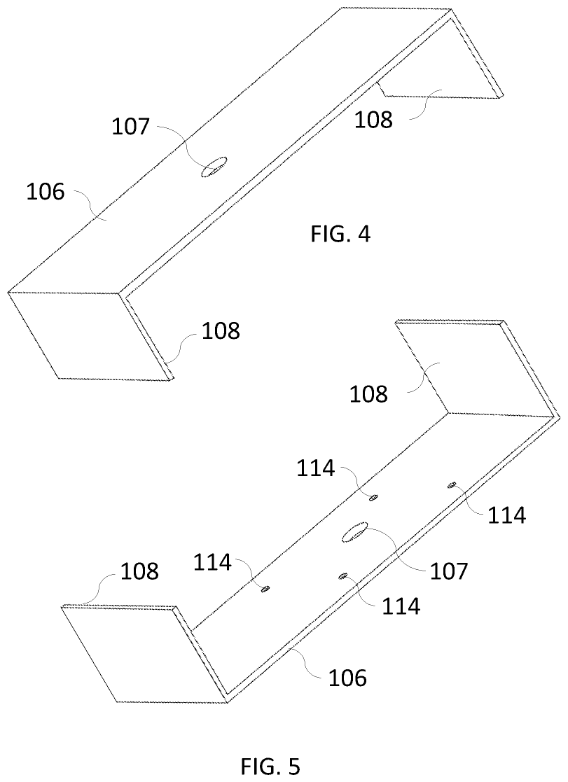

FIGS. 4 and 5 illustrate perspective views of an example cover 106 that is used to cover a detection device 102. The cover 106 includes a top with two sides 108 that extend perpendicularly from the top. The top and sides are generally flat and planar. The top has a central opening 107 that is dimensioned to allow the arm 111 of the detection device 102 to be removably inserted.

A bottom surface of the top comprises a plurality of contact areas, such as the four rounded, dome-like recesses 114 shown that are spaced around the central opening 107. The four recesses 114 are to contact the set of contacts 112 on top of the detection device 102. Each recess may be located between the central opening and a side lengthwise and between the central opening and top edge widthwise. The recess may be at a midpoint between the central opening and a side or top edge or other location. Each recess may be equidistant from each other. The recesses may have two opposing recesses within a first distance from the central opening and two other opposing recesses within a second distance from the central opening, the first and second distances being distinct from one other.

Variations include that recesses for the cover be replaced by contact areas 114 that extend outward. Corresponding contact areas comprising bumps 112 of the body 103 would be replaced by recesses and then alignment and contact would still occur as before.

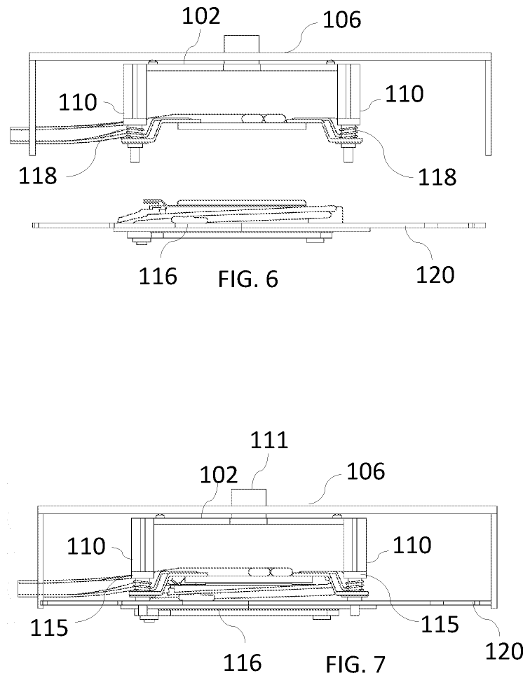

FIG. 6 illustrates an exploded view of the cover 106, detection device 102, elongated legs 110, heatsink componentry 118, heatsink 116, and board 120 prior to assembly. Particularly, the cover 106, detection device 102, and heatsink componentry 118 are attached together and shown separated from the heatsink 116 and board 120. The heatsink componentry 118 is aligned with and mounted to the heatsink 116 and board 120 during installation.

The first set of contact areas 112 are nested within the contact areas 114 underneath the cover. The length of the first set of contact areas 112 extend above the planar surface of the body 103 so as to define a fixed spatial clearance between the bottom of the planar surface of the cover 106 and a top surface of the body 103 when the cover 106 is placed on the body 103. The cover 106 and the body 103 do not contact each other except for their respective contact areas. This allows the cover and the body to be aligned by tactile sensory movement, in other words, by feeling or otherwise locating their respective contact areas to align the cover with the body. The space between the cover and the body also allows the cover 106 space to be moved in various directions by the arm 111.

Variations include that the cover 106 and the body 103 be in contact such that the cover 106 rests with its bottom surface mounted flush with the top planar surface of the body 103.

A method for physically detecting a correct assembly position of a heatsink may include several steps. The heatsink is first mounted on to a board, for example, with screws, compressed spring screws, mounting clips, brackets, tape and epoxy. Screws used to attach the heatsink to the board may be secured with ends of the screws tightened to nuts located underneath the board.

The heatsink may be mounted so that there is an even load distribution of spring force at all four corners of the heatsink to hold the heatsink in place. One or more fans may also be mounted to the heatsink or board. If the heatsink has an uneven force distribution, undesired stresses and strains may develop that affect functionality of the heatsink. Similarly, if the heatsink is not screwed, imbalances of the heatsink can affect heat dissipation in a way that negatively affects functionality of the CPU. The detection device may be used to detect such problems when structural effects on the heatsink from the various forces become present.

A detection device 102 is mounted on at least three contact areas of heatsink componentry. The elongated legs 110 are aligned with the contact areas to assist in mounting the detection device. Free ends of the elongated legs 110 may rest on top of the contact areas 115 of the heatsink. Criss-cross free ends are to balance on top of the contact areas. Alternatively, the contact areas may have recesses, such as recesses within the tops of screws. The recesses may be defined by annular rims on top of the screws and free ends may be removably inserted within the recesses. The detection device may further be attached or fastened to the heatsink componentry to prevent the detection device from being moved.

The cover 106 is aligned with the detection device 102 and placed over the detection device 102. The first set of contact areas 112 are aligned with contact areas 114 underneath the cover 106. The second set of contact areas 110 are aligned with contact areas 115 on the heatsink componentry.

FIG. 7 illustrates a fully assembled detection device 102 sandwiched between a cover 106 and heatsink 116 on a board 120. With additional reference to FIGS. 1 and 5, the first set of contact areas 112 of the body 103 are in contact with contact areas 114 of the cover 106. The second set of contact areas 110 of the body 102 are in contact with heatsink componentry.

The cover 106 has a width that is generally the same as the width of a detection device. The cover 106 has a length that is greater than the width of the body 103. Because of the length, the sides of the cover 106 may be placed on the board so as to provide a space on either side of the heatsink 116.

As shown in FIG. 7, the cover is placed on the board so as to define an equal space on either side of the heatsink 116, heatsink componentry 118, and elongated legs 110 of the body 103. The space is dimensioned to allow for the heatsink 116 and heatsink componentry 118. The space is dimensioned to allow for lateral movement of the detection device between sides of the cover 106. It also provides space for air flow and heat dissipation around the heatsink 116.

Free ends of the sides of the cover extend to outer edges or below outer edges of the board. Variations include that the free ends of the cover contact top surfaces of the board if the board has a length and width that is greater than the length and width of the cover. Attachments and snap fits are also anticipated with the cover being mounted to the board.

The elongated legs 110 have a length that provides an extra space between the planar surface of the body 103 and the top surface of the heat sink. The extra space provided between the planar surface and top surface of the heat sink may be approximately equal to the thickness of a heatsink, the thickness of a heatsink plus the thickness of a board, or a thickness that is greater than a heatsink plus the thickness of a board. When an incorrect assembly occurs causing the elongated legs to contact the board instead of the heatsink componentry, the elongated legs may still provide an extra space between the planar surface of the body and the top surface of the heatsink and heatsink componentry.

Sides of the cover provide a sufficient clearance between the top of the cover and the board to house the detection device, the heatsink, and the heatsink componentry, including one or more fans, etc., as well as extra space as desired. The elongated legs have lengths that allow the cover to fit properly on the board with sides of the cover extending to the board or being mounted to the board properly. The elongated legs also provide a sufficient clearance between the body of the detection device to house the heatsink and heatsink componentry and provide the extra space as desired.

Free end surfaces of the elongated legs 110 are in contact with heatsink componentry screws 118. The flat contact surfaces 115 of the screws 118 are to balance the elongated legs 110. The arm 111 is properly aligned with and inserted within the opening 107 of the cover 106. The entire assembly is thus correct.

Because the cover 106 is able to cover the detection device 102 and have sides 108 in contact with, attached to, or otherwise mounted on the board 120, assurance is provided that the heatsink 116 is properly attached and that the cover 106 is properly aligned with respect to the detection device 102 and heatsink 116. A visual inspection may further aid in confirming that the heatsink 116 is properly attached. For example, when the cover 106 lays parallel with the planar surface 104 of the body 103 of the detection device 102, this provides a visual indication that the heatsink 116 is properly installed.

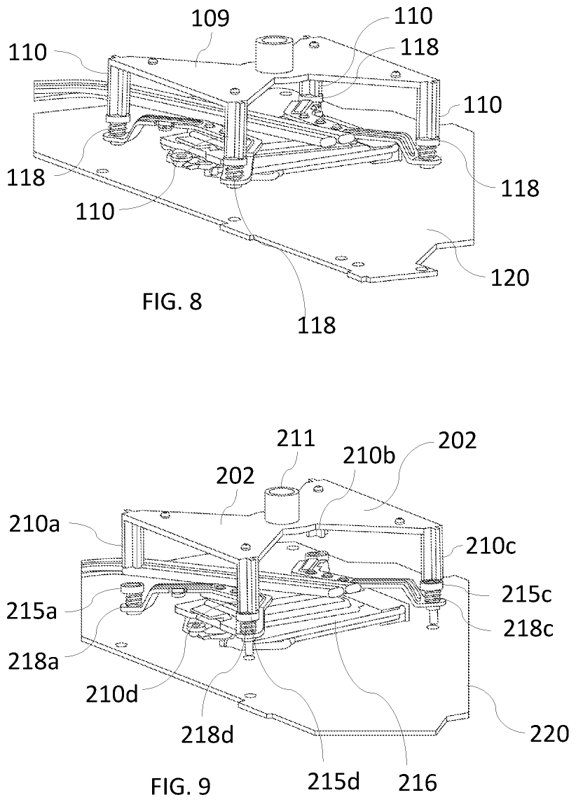

FIG. 8 illustrates a perspective view of a correctly assembled heatsink 116, clearly showing elongated legs 110 mounted with free ends flush with heatsink componentry screws 118, which indicates that the heatsink 116 is correctly installed on the board 120.

An incorrect assembly position of a heatsink is indicated when points of contact with the heatsink componentry and the CPU cover are incorrect. FIG. 9 offers a contrasting perspective view of FIG. 8 by illustrating an example of an incorrect assembly of the heatsink 216. Particularly, elongated leg 210a does not touch respective contact area 215a of the heatsink componentry screw 218a. An imbalance is caused by screws 215c and 215d not being completely screwed into the board 220. Also, there is a missing screw in the back corner where elongated leg 210b would ordinarily be in contact.

Even if the arm 211 is manipulated to move the detection device, a level balance of all elongated legs 210a, 210b, 210c, and 210d will not be achieved because of the gap where the missing screw in the back corner would normally be. Also, the heatsink componentry screws 218c and 218d extend higher than the heatsink componentry screw 215a relative to the board 220, which further prevents the detection device 202 from being level relative to the board 220.

Consequently, the elongated legs 210a, 210b, 210c, and 210d do not balance on respective heatsink componentry screws. This type of an incorrect assembly position results in the cover not being level so that it is unable to be placed on the board with free ends of its sides contacting the board 220. The cover and detection device must be removed. The heatsink componentry screws 218c and 218d must be properly screwed onto the board 220. The missing screw must be also be properly screwed onto the board. Then the detection device and the cover may be remounted on to the board.

Other examples of incorrect assembly positions include a single elongated leg or more than two elongated legs not contacting the heatsink componentry.

Also, the type of contact may cause an imbalance. For example, one or more elongated legs may be angled or otherwise imbalanced on a respective contact area of the heatsink componentry, causing the detection device to be imbalanced and unsteady relative to the circuit board 120. Other types of incorrect assembly positions are anticipated.

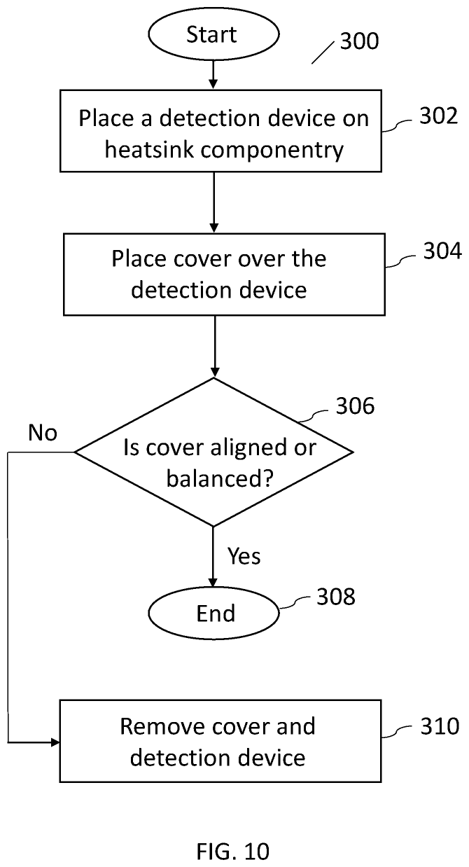

FIG. 10 provides a flow chart of an example method 300 for detecting whether or not the heatsink is assembled correctly with a detection device. The method 300 in FIG. 10 starts when a detection device (block 302) is placed on heatsink componentry as discussed herein. A cover is then placed over the detection device (block 304).

In the situation that the cover is not properly aligned or balanced relative to the heatsink componentry that is mounted on the heatsink (block 306), more likely than not resulting from an incorrect assembly position or imbalance, the cover 106 and detection device 102 may be removed (block 310). The cover and detection device may then be removed (block 310) and the heatsink 116 may reinstalled.

Prior to removing the cover 106, however, the detection device 102 can be moved to test whether or not it is properly placed on the heatsink 116. To this end, the arm 111 can be manipulated to move the detection device 102 relative to the heatsink 116 and the heatsink componentry 118. Manipulation may be accomplished with an instrument, such as a screwdriver or other instrument that is inserted within the hollowed opening of the arm and used to move the arm 111 axially, laterally, and vertically with respect to the heatsink 116. Even a slight adjustment may correct a situation where the detection device 102 is accidently not correctly balanced on the heatsink componentry 118. In this manner, one may be able to correct the situation in an efficient manner, and without having to remove the cover 102. If the arm can balance the detection device, then the cover should be able to be mounted on the board in a balanced manner.

If manipulating the detection device 102 with the arm 111 is unsuccessful in correcting the position of the detection device 102 relative to the heatsink 116, then the cover 106 and the detection device 102 can be removed and the heatsink 116 reinstalled.

The preceding description has been presented only to illustrate and describe examples of the principles described. This description is not intended to be exhaustive or to limit these principles to any precise form disclosed. Many modifications and variations are possible in light of the above teaching.

What is claimed is:

1. A detection device, comprising:
a body;
a first set of at least three contact areas on the body to contact a corresponding set of at least three contact areas of a a central processing unit (CPU) cover; and
a second set of at least three contact areas on the body to contact a set of at least three contact areas on heatsink componentry,
wherein an incorrect assembly position of a heatsink is indicated when points of contact with the heatsink componentry and the CPU cover are incorrect.

2. The detection device of claim 1, wherein the body further comprises a flat upper surface that is parallel with a surface of a CPU cover when the heatsink and the body are in a correct assembly position.

3. The detection device of claim 1, wherein the first set of at least three contact areas comprises extended members or protrusions from the body.

4. The detection device of claim 1, wherein the first set of at least three contact areas comprises raised bumps with rounded outer surfaces.

5. The detection device of claim 1, wherein the second set of at least three contact areas comprises elongated legs that extend outward from the body.

6. The detection device of claim 5, wherein the elongated legs extend outward from the body in a parallel manner.

7. The detection device of claim 5, wherein the elongated legs extend outward from opposing corners of the body.

8. The detection device of claim 5, wherein the elongated legs extend in an opposite direction from the at least three contact areas in the first set.

9. The detection device of claim 1, the device further comprising an arm that extends outward from the body to be slidably received through an opening of the CPU cover, the arm to align the body with the cover.

10. The detection device of claim 9, the arm further comprising a hollow central opening therethrough.

11. A method for physically detecting a correct assembly position of a heatsink, comprising:
placing a detection device on at least three contact areas of heatsink componentry;
placing a cover over the detection device; and
removing the cover and the detection device if the cover is not properly aligned or balanced relative to the heatsink componentry that is mounted on the heatsink.

12. The method of claim 11, further comprising:
removably inserting an arm of the detection device through an opening of the cover to align the cover relative to the detection device and the heatsink.

13. The method of claim 11, further comprising:
positioning a plurality of legs of the detection device on the heatsink componentry to align or balance the detection device relative to the heatsink.

14. A detection device, comprising:
a body;
a plurality of top contact areas on a top surface of the body; and
a plurality of bottom contact areas on a bottom surface of the body,
the plurality of top contact areas positioned to align with and contact corresponding contacts on a cover and the plurality of bottom contact areas positioned to align with and contact corresponding contacts on heatsink componentry when the heatsink is assembled correctly.

15. The detection device of claim 14, further comprising an arm that extends upward relative to the top surface of the body to be removably inserted into an opening of the cover for alignment of the device with the cover.
